(19) United States
(12) Patent Application Publication
(10) Pub. No.: US 2024/0291229 A1
(43) Pub. Date: Aug. 29, 2024

(54) LIGHT EMISSION DEVICE

(71) Applicant: NICHIA CORPORATION, Anan-shi, Tokushima (JP)

(72) Inventor: Soichiro MIURA, Tokushima-shi (JP)

(73) Assignee: NICHIA CORPORATION, Anan-shi, Tokushima (JP)

(21) Appl. No.: 18/570,536

(22) PCT Filed: Jun. 21, 2022
(86) PCT No.: PCT/JP2022/024778

§ 371 Date: Dec. 14, 2023

(30) Foreign Application Priority Data
Jun. 29, 2021 (JP) 2021-107791

(51) Int. Cl. H01S 5/02253; H01S 5/02257; H01S 5/023; H01S 5/042

(52) U.S. Cl. CPC H01S 5/02253; H01S 5/02257; H01S 5/023; H01S 5/042

(57) ABSTRACT

A light emitting device includes three or more light emitting elements, and a package that includes a base having a mounting face on which the three or more light emitting elements are disposed and a lateral wall part disposed around the light emitting elements and having a light transmitting incident face. The three or more light emitting elements include a first light emitting element that emits first light having an emission peak at a first wavelength along a first optical axis, a second light emitting element that emits second light having an emission peak at a second wavelength along a second optical axis, and a third light emitting element that emits third light having an emission peak at a third wavelength along a third optical axis. An angle formed by the first optical axis and the second optical axis in a top view is 3° to 45°. As the first light and the second light respectively travel along the first optical axis and the second optical axis, a first interval between the first optical axis and the second optical axis increases. The exiting first, second, and third lights are incident on the incident face.

### TECHNICAL FIELD

The present disclosure relates to a light emitting device.

### BACKGROUND ART

Technological development efforts are being made to reduce the size of a light emitting device package.

Patent Document 1 discloses a laser diode module equipped with a plurality of laser diodes, a plurality of mirrors for reflecting the laser beams respectively emitted from the laser diodes, and a convergence lens for converging the laser beams reflected by the mirrors. In the laser diode module, the laser diodes are disposed such that the intervals between the laser beams from the adjacent laser diodes gradually increases. The maximum angle formed by two optical axes of the laser beams from two adjacent laser diodes is set, for example, as 1.5°. The mirrors are disposed to reflect the laser beams towards the convergence lens such that the interval between the laser beams from two adjacent laser diodes gradually decreases. The Patent Document 1 states that the disclosed structure can reduce the size of a laser diode module without a reduction in the laser beam combining efficiency.

### CITATION LIST

### Patent Literature

Patent Document 1: JP 2015-31739 A

### SUMMARY OF INVENTION

### Technical Problem

There is a need for miniaturizing a light emitting device.

### Solution to Problem

A light emitting device according to an exemplary and non-limiting embodiment includes three or more light emitting elements, and a package that includes a base having a mounting face on which the three or more light emitting elements are disposed and a lateral wall part disposed around the three or more light emitting elements and having a light transmitting incident face. The three or more light emitting elements include a first light emitting element that emits first light having an emission peak at a first wavelength from a first emission point along a first optical axis, a second light emitting element that emits second light having an emission peak at a second wavelength from a second emission point along a second optical axis, the second wavelength being different from the first wavelength, and a third light emitting element that emits third light having an emission peak at a third wavelength from a third emission point along a third optical axis, the third wavelength being different from the first wavelength and the second wavelength. An angle formed by the first optical axis and the second optical axis in a top view when viewed in a first direction that is a direction normal to the mounting face is 3° to 45°. As the first light and the second light respectively travel along the first optical axis and the second optical axis, a first interval between the first optical axis and the second optical axis increases. The exiting first, second, and third lights respectively from the first, second, and third light emitting elements are incident on the incident face.

### Advantageous Effects of Invention

According to an embodiment of the present disclosure, a light emitting device allowing for package miniaturization can be provided.

### BRIEF DESCRIPTION OF DRAWINGS

FIG. 1 is a perspective view of a light emitting device according to first to third embodiments of the present disclosure.

FIG. 2 is a perspective view of the light emitting device according to the first embodiment in the state in which the second cap and the lid are removed.

FIG. 3 is a cross-sectional view of the light emitting element in the state of not having the second cap and the lid taken along line III-III in FIG. 2.

FIG. 4 is a perspective view of the light emitting device according to the first embodiment in the state in which the first cap, the second cap, and the lid are removed.

FIG. 5 is a top view corresponding to the perspective view shown in FIG. 4.

FIG. 6 is a top view illustrating the wiring in the interior of the package.

FIG. 7 is a diagram illustrating the structure of a lens member.

FIG. 8 is a schematic diagram showing how the light from each of the light emitting elements is incident on the incident face and exits the emission face of the lens member.

FIG. 9 is a schematic diagram showing the emission end faces and the lateral faces of the light emitting elements mounted on a submount when viewed in the Z direction.

FIG. 10A is a schematic diagram illustrating an example of how the first light traveling along the first optical axis spreads in the optical path until it enters the lens member.

FIG. 10B is a schematic diagram illustrating another example of how the first light traveling along the first optical axis spreads in the optical path until it enters the lens member.

FIG. 11A is a schematic diagram illustrating a first variation of the layout of the light emitting elements.

FIG. 11B is a schematic diagram illustrating a second variation of the layout of the light emitting elements.

FIG. 11C is a schematic diagram illustrating a third variation of the layout of the light emitting elements.

FIG. 12A is a schematic diagram illustrating an example of the layout of four light emitting elements disposed on a submount.

FIG. 12B is a schematic diagram illustrating another example of the layout of four light emitting elements disposed on a submount.

FIG. 13 is a perspective view of a light emitting device according to the second embodiment of the present disclosure in the state in which the second cap and the lid 130 are removed.

FIG. 14 is a diagram showing an example of an integrally formed lens member.

FIG. 15 is a diagram showing another example of an integrally formed lens member.

FIG. 16A is a perspective view of an example of a substrate included in the light emitting device according to the second embodiment of the present disclosure.

FIG. 16B is a cross-sectional view of the light emitting device according to the second embodiment taken along line XVIB-XVIB in FIG. 13.

FIG. 17A is a top view of a light emitting device according to the third embodiment of the present disclosure in the state in which the second cap, the lid, and the first cap are removed.

FIG. 17B is a cross-sectional view taken along line XVIIB-XVIIB in FIG. 17A.

FIG. 18 is a top view of a variation of the light emitting device according to the third embodiment of the present disclosure in the state in which the second cap, the lid, and the first cap are removed.

FIG. 19 is a schematic lateral side view of an example of a head-mounted display according to an embodiment of the present disclosure.

### DESCRIPTION OF EMBODIMENTS

In the present specification and the scope of claims, a polygon, such as a triangle, rectangle, or the like, is not limited to those in the strict mathematical sense, and includes a shape subjected to processing, such as cutting angles, chamfering, beveling, rounding, or the like. Moreover, the location of such processing is not limited to a corner (an end of a side) of a polygon. Rather, a shape subjected to processing in the intermediate portion of a side will similarly be referred to as a polygon. In other words, any polygon-based shape subjected to partial processing should be understood to be included in the interpretation of a “polygon” disclosed in the present specification and the scope of claims. This similarly applies to any word describing a specific shape, such as a trapezoidal, circular, recessed, or projected shape, without being limited to a polygon. This also similarly applies to the sides defining such shapes. In other words, even if a corner or intermediate portion of a side is subjected to processing, the term “side” should be interpreted to include the processed portion. To distinguish a “polygon” or “side” that is intentionally not processed from a shape subjected to processing, the shape will be described by adding the phrase “exact,” such as “an exact rectangle.”

In the description or the accompanying claims, moreover, when there are multiple pieces of elements having the same designation and a distinction must be made, a word such as “first,” “second,” or the like might occasionally be added to the element designation. In the case where a claim includes a description, “light emitting elements are disposed on a substrate,” for example, the specification might include a description. “a first light emitting element and a second light emitting element are disposed on a substrate.” The words, “first” and “second,” are used to distinguish the two light emitting elements. There might be an occasion where the element designation with the same distinguishing word in the scope of claim and the description do not refer to the same element. For example, in the case where the description describes the elements that are identified by the terms, “first light emitting element.” “second light emitting element,” and “third light emitting element,” the “first light emitting element” and “second light emitting element” in the scope of claims might correspond to the “first light emitting element” and “third light emitting element” in the description. In the case in which the term “first light emitting element” is used, but the term “second light emitting element” is not used in claim 1 of the scope claims, moreover, the invention according to claim 1 has only to have one light emitting element, and the light emitting element is not limited to the “first light emitting element” in the description, and can be the “second light emitting element” or the “third light emitting element” in the description.

In the description or the scope of claims, terms indicating specific directions or positions (e.g., “upward/upper,” “downward/lower,” “right,” “left,” “front,” or “rear”) might be used. These terms, however, are merely used in order to make the relative directions or positions in the drawings being referenced more easily understood. As long as the relationship between relative directions or positions indicated with the terms such as “upward/upper,” “downward/lower,” or the like is the same as those in a referenced drawing, the layout of the elements in other drawings, or actual products and manufacturing equipment outside of the present disclosure, does not have to be the same as those shown in the referenced drawing.

The dimensions, dimensional ratios, shapes, spacing, and the like of the constituent elements shown in the drawings might be exaggerated for clarity of explanation. Certain elements might be omitted in a drawing so as not to make the drawing excessively complex.

Certain embodiments of the present invention will be explained below with reference to the accompanying drawings. The embodiments described below are illustrations provided for the purpose of giving shape to the technical ideas of the present invention, and are not intended to limit the present invention. The numerical values, shapes, materials, and the like used in the explanation of the embodiments are merely examples, and are modifiable as long as such a modification does not cause any technical inconsistency. In the explanation below, the same designations and reference numerals denote identical members or similar members, for which redundant explanation will be omitted as appropriate.

### First Embodiment

The general structure of a light emitting device according to an embodiment will be explained with reference to FIG. 1 to FIG. 6. FIG. 1 to FIG. 6 are drawings illustrating a light emitting device 200 as an embodiment. In the accompanying drawings, X-axis, Y-axis, and Z-axis that are orthogonal to one another are provided for reference purposes.

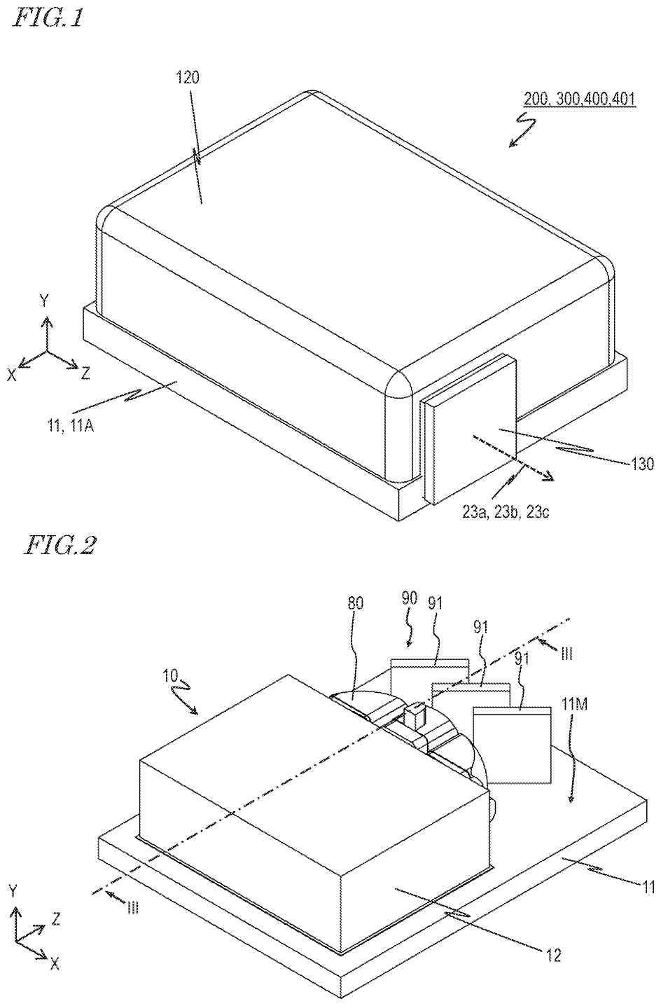

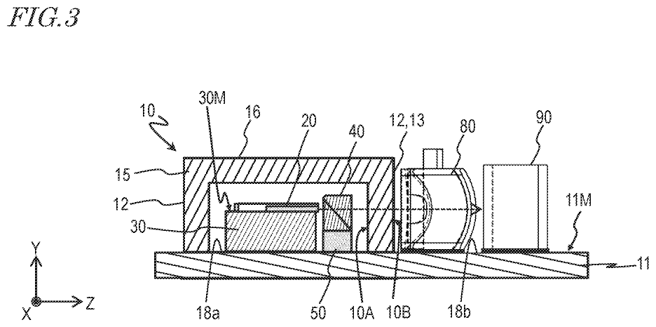

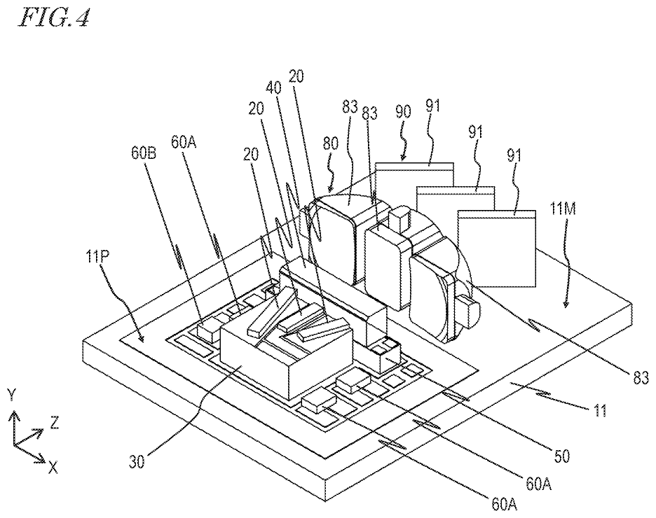

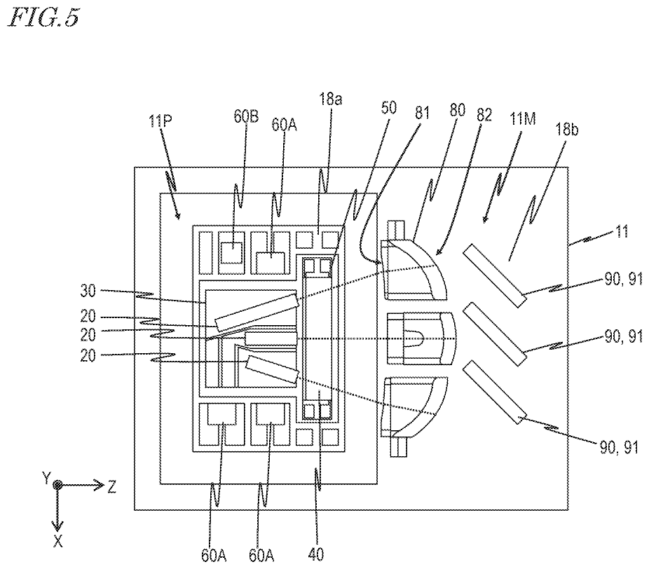

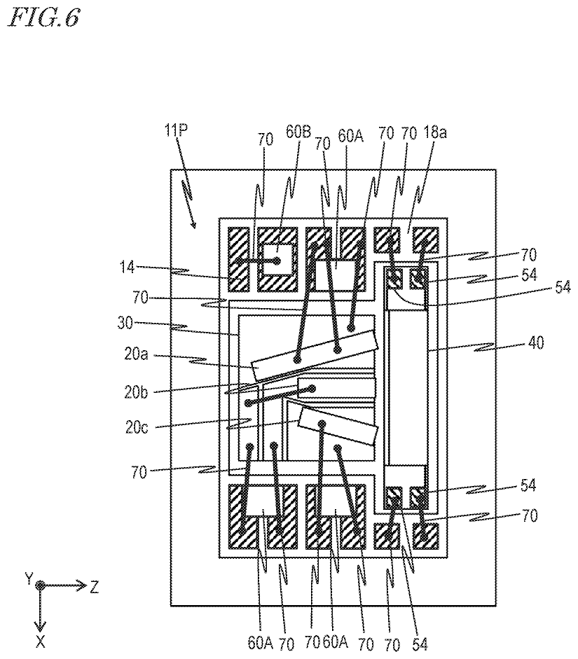

FIG. 1 is a perspective view of the light emitting device 200. FIG. 2 is a perspective view of the light emitting device 200 from which the second cap 120 and the lid 130 are removed. FIG. 3 is a cross-sectional view of the light emitting device 200 in the state in which the second cap 120 and the lid 130 are removed taken along line III-III in FIG. 2. In FIG. 3, the portion of the light from a light emitting element 20 traveling along the optical axis is indicated by a dotted line. FIG. 4 is a perspective view in the state in which the first cap 16 and the second cap 120 are removed from the light emitting device 200. FIG. 5 is a top view corresponding to the perspective view in FIG. 4. In FIG. 5, the portions of the light from the three light emitting elements 20 traveling along the optical axes are indicated by dotted lines. FIG. 6 is a top view illustrating the wiring on the inside of the package 10.

The light emitting device 200 according to this embodiment includes a substrate 11, a first cap 16, and a plurality of light emitting elements 20. The light emitting device 200 illustrated in the drawings further includes a submount 30, an optical member 40, a light detector 50, one or more protective devices 60A, a temperature measuring element 60B, one or more lens members 80, a beam combiner 90, a second cap 120, and a lid 130. However, these elements are not essential.

In the light emitting device 200 illustrated in the drawings, the light emitting elements 20, the submount 30, the optical member 40, the light detector 50, the protective devices 60A, and the temperature measuring element 60B are disposed in the space defined by the substrate 11 and the first cap 16. The lens member 80 and the beam combiner 90 are disposed on the outside of the first cap 16.

The light emitting device 200 according to this embodiment is generally box shaped. The size in the X direction can be, for example, 10 mm or smaller, the size in the Z direction can be, for example, 15 mm or smaller. The height in the Y direction can be, for example, 4 mm or smaller.

Constituent elements will be explained.

### Substrate 11

The substrate 11 in the example shown in the drawings is flat plate shaped. The substrate 11 has an upper face and a lower face that opposes the upper face. The upper face functions as the mounting face 11M on which one or more constituent elements of the light emitting device 200 are disposed. The mounting face 11M is a flat face, and includes a first mounting region 18a and a second mounting region 18b. The substrate 11 can be formed by using a ceramic as a main material. Examples of ceramics include aluminum nitride, silicon nitride, aluminum oxide, silicon carbide, and the like.

### First Cap 16

A first cap 16 includes a lateral wall part 12 and an upper part 15. The first cap 16 has a recessed shape. The outline of the first cap 16 in a top view is rectangular. However, the outline of the first cap 16 does not have to be rectangular, and may be polygonal other than rectangular, circular, or the like. The inner space surrounded by the substrate 11, the lateral wall part 12, and the upper part 15 is a sealed space that is airtight.

The lateral wall part 12 surrounds the first mounting region 18a of the substrate 11, and extends upwards from the mounting face 11M. The one or more constituent elements disposed in the first mounting region 18a are surrounded by the lateral wall part 12. On the other hand, the constituent elements disposed in the second mounting region 18b are not surrounded by the lateral wall part 12. The upper part 15 is connected to the lateral wall part 12 above the mounting face 11M. The upper part 15 is positioned immediately above the constituent elements disposed in the first mounting region 18a.

The first cap 16 can be formed from a light transmissive material, such as glass, plastic, quartz, sapphire, or the like, by utilizing a processing technology such as molding or etching. The first cap 16 may be formed by separately forming the upper part 15 and the lateral wall part 12 from different main materials, followed by bonding the two. For example, the main material for the upper part 15 can be a non-light transmissive material such as monocrystalline or polycrystalline silicon, and the main material for the lateral wall part 12 can be a light transmissive material such as glass.

In the example shown in the drawings, the first cap 16 combined with the substrate 11 is referred to as a package 10. In a top view when viewed in the Y direction which is a direction normal to the mounting face 11M of the substrate 11, the outline of the package 10 is rectangular. However, the outline of the package 10 does not have to be rectangular, and can be polygonal other than rectangular, or circular. The “package” in this embodiment is not limited to this. In this embodiment, the “package” can be an overall structure having a “base” on which one or more members are disposed and a “lateral wall part” that surrounds the one or more members. The “substrate 11” and the “lateral wall part 12” illustrated in the drawings are examples of the “base” and the “lateral wall part.”

The package 10 in the example shown in the drawings will be explained next. As illustrated in FIG. 6, the package 10 has a plurality of wiring regions 14 for achieving electrical connection. The wiring regions 14 are provided in the first mounting region 18a. Instead of marking all the wiring regions 14 with a reference numeral, the same hatching is applied to the wiring regions 14 in FIG. 6. The wiring regions 14 can be electrically connected to the wiring regions provided on the lower face of the substrate 11 (the face opposite the mounting face 11M) through via holes that go through the substrate 11. The wiring regions to be electrically connected to the wiring regions 14 may be provided on another outer surface of the package 10 besides the lower face of the substrate 11, such as the upper face or outer lateral faces.

As shown in FIG. 6, the package 10 has a light incident face 10A and a light extraction face 10B which transmit light as part of the lateral wall part 12. At least one of the one or more outer lateral faces of the lateral wall part 12 can function as the light extraction face 10B. The light extraction face 10B can be perpendicular to the mounting face 11M. Being perpendicular here includes a tolerance of up to +5 degrees. The light extraction face 10B may be oblique to the mounting face 11M.

At least a region in the light extraction face 10B has light transmissivity. This region having light transmissivity is referred to as the light transmitting region 13 (see FIG. 6). Here, “having light transmissivity” means having an 80% transmittance or higher with respect to the main portion of the incident light. The light transmitting region 13 may extend multiple outer lateral faces of the package 10. The region having light transmissivity in the package 10 does not have to be limited to the light transmitting region 13. The package 10 illustrated in the drawings has four outer lateral faces corresponding to the rectangular outline. All of the four outer lateral faces have light transmissivity. One of the four outer lateral faces is the light extraction face 10B.

The mounting face 11M of the substrate 11 further includes a peripheral region 11P. The peripheral region 11P in the mounting face 11M is located around the first mounting region 18a on which certain constituent elements are disposed. The wiring regions 14 are surrounded by the peripheral region 11P. The first cap 16 is bonded to the peripheral region 11P of the substrate 11. A metal film can be formed on the peripheral region 11P for bonding purposes. The wiring regions 14 can be formed from a conductor such as a metal, including a patterned metal film.

### Second Cap 120

In the light emitting device 200 illustrated in the drawings, similar to the first cap 16, the second cap 120 has a recessed shape. The outline of the second cap 120 in the top view is rectangular. The area of the upper face of the second cap 120 is larger than the area of the upper face of the first cap 16 in the top view, i.e., when viewed in a direction normal to the mounting face 11M of the substrate. The second cap 120 is secured to the substrate 11. The second cap 120 is bonded to the peripheral region along the outer perimeter of the mounting face 11M. Bonding the second cap 120 to the substrate 11 creates an inner space in the second cap 120. The inner space, similar to the inner space of the first cap 16, is a sealed space, but does not have to be airtight. The second cap 120 can house all of the constituent elements that are disposed on the mounting face 11M of the substrate 11, in the inner space.

The example of second cap 120 illustrated has an opening in a lateral side view when viewed in the Z direction. The second cap 120 can be formed with a light shielding material that blocks light. For example, the second cap 120 can be produced by applying a light shielding film on the surfaces of a formed body formed from glass.

### Lid 130

A lid 130 has light transmissivity. The lid 130 illustrated in FIG. 1 is flat plate shaped. The lid 130 is bonded to the substrate 11 and the second cap 120. The lid 130 covers the opening provided in the second cap 120. Closing the opening of the second cap 120 with the lid 130 can make the inner space of the second cap 120 a closed space.

### Light Emitting Element 20

An example of light emitting element 20 is a semiconductor laser element (or laser diode). The light emitting element 20 can have a rectangular outer shape in the top view. In the case where the light emitting element 20 is an edge-emitting type semiconductor laser element, the lateral face meeting one of the two short sides of the rectangle is the emission end face. The upper face and the lower face of the light emitting element 20 are larger in area than the emission end face. The light emitting element 20 is not limited to an edge-emitting type semiconductor laser element, and may be a surface-emitting type semiconductor laser element such as a vertical-cavity surface-emitting laser (VCSEL), or a light emitting diode (LED).

The light emitting element 20 in this embodiment has one or more emission points in the emission end face. The light emitting element 20 may be a single emitter, which has one emission point in the emission end face, or a multi-emitter which has two or more emission points in the emission end face. The light emitting elements 20 illustrated are single emitters.

Here, the explanation of an edge-emitting type light emitting element 20 will be supplemented. The light emitted from the emission end face of a semiconductor laser element (laser light) is diverging light which spreads. The laser light forms an elliptical far field pattern (hereinafter referred to as “FFP”) in a plane parallel to the emission end face. An FFP represents the shape and the light intensity distribution of the emitted light at a position that is distant from the emission end face.

The light passing the center of the elliptical FFP, in other words, the light having the peak intensity in the light intensity distribution of the FFP will be referred to as the light travelling along the optical axis. The optical path of the light travelling along the optical axis is referred to as the optical axis of the light. In this embodiment, the light having an intensity of at least 1/e² relative to the peak intensity value in the light intensity distribution of an FFP will be referred to as the “main portion” of the light, and the light having an intensity below 1/e² relative to the peak intensity value will be referred to as the “peripheral portion” of the light in order to distinguish the main portion of light from the peripheral portion of light. The “main portion” and the “peripheral portion” of light may be distinguished by using the beam diameter at which the intensity in the FFP intensity distribution becomes one half of the peak intensity value that is referred to as the “full width at half maximum.”

In the elliptical shape of an FFP of the emitted light from a semiconductor laser element 20, the major axis direction will be referred to as the fast axis direction, and the minor axis direction will be referred to as the slow axis direction. The layers including an active layer that constitute the semiconductor laser element can be stacked in the fast axis direction.

Based on the light intensity distribution of an FFP, the angle corresponding to the lie-intensity of the light intensity distribution is referred to as the beam divergence angle of the light from the semiconductor laser element. The beam divergence angle in the fast axis direction is referred to as the fast axis direction divergence angle, and the beam divergence angle in the slow axis direction is referred to as the slow axis direction divergence angle. The slow axis direction divergence angle of the light emitted from the semiconductor laser element is 3° or larger.

For the light emitting element 20, for example, a semiconductor laser element that emits blue, green, or red light can be employed. A semiconductor laser element that emits light other than these may be employed.

Here, blue light refers to light having a peak emission wavelength in the 420 nm to 494 nm range. Green light refers to light having a peak emission wavelength in the 495 nm to 570 nm range. Red light refers to light having a peak emission wavelength in the 605 nm to 750 nm range.

Blue or green light emitting semiconductor laser elements are, for example, semiconductor laser elements including nitride semiconductors. For nitride semiconductors, for example, GaN, InGaN, and AlGaN can be used. Examples of red light emitting semiconductor laser elements include those including InAlGaP based, GalnP based, GaAs based, and AlGaAs based semiconductors.

### Submount 30

As illustrated in FIG. 4, the submount 30 having an upper face 30M and a lower face located opposite the upper face 30M can have a cuboid shape. The upper face 30M and the lower face each function as a bonding face. The distance between the upper face 30M and the lower face is smaller than the distance between two other opposing faces. The shape of the submount 30 is not limited to a cuboid. The submount 30 can be formed from, for example, silicon nitride, aluminum nitride, or silicon carbide. A metal film for bonding purposes is provided on each of the upper face 30M and the lower face. One or more wiring regions can be provided on the upper face 30M to be electrically connected to another constituent element.

### Optical Member 40

An optical member 40 has a partially reflecting face. The partially reflecting face reflects a portion of the incident light while transmitting the remaining light. The partially reflecting face functions as a beam splitter. The light became incident on the partially reflecting face is split into two that travel in different directions. The two divided light include the same wavelength light. The optical member 40 divides the incident light of the same wavelength components into two using predetermined percentages. For example, one of the two parts of light divided by the optical member 40 is used as main light (hereinafter referred to as “main light”), while the other part is used as monitoring light for controlling the main light (hereinafter referred to as “monitor light”). The optical member 40 in this embodiment, as illustrated in FIG. 3 and FIG. 4, can be a cuboid. A notch may be provided on one of the long sides where the upper face meets the lateral face. Providing such a notch makes it easier to identify the orientation of the reflecting face, improving the case of installation.

In the case of splitting the incident light into main light and monitor light, the intensity of the monitor light is lower than the intensity of the main light. The partially reflecting face transmits, for example, 80% to 99.5% of the incident light, while reflecting 0.5% to 20.0% of the incident light.

### Light Detector 50

A light detector 50 has a bonding face, a light receiving face, and lateral faces. The light receiving face is located opposite the bonding face. The outer shape of the light detector 50 is a cuboid. The outer shape may be different from a cuboid.

The light receiving face has a rectangular outline, and the length of the light receiving face in the X direction is larger than the length in the Z direction. The light receiving face can be provided with multiple light receiving regions. An example of a light detector 50 having a light receiving face is a photoelectric conversion element (photodiode) that outputs an electric signal in accordance with the intensity or the amount of the incident light.

The light detector 50 has multiple wiring regions 54. The wiring regions 54 can be provided on the light receiving face. The wiring regions 54 may be provided on a face other than the light receiving face, for example, a lateral face. The wiring regions 54 are electrically connected to the light receiving regions. Wiring can be disposed on the light receiving face for electrically connecting the wiring regions 54 and the light receiving regions.

### Protective Device 60A

A protective device 60A is a circuit element that prevents excessive current from flowing through and destroying a certain element (for example, a light emitting element 20). A typical example of the protective device 60A is a constant voltage diode such as Zenor diode. For the Zenor diode, a Si diode can be employed.

### Temperature Measuring Element 60B

A temperature measuring element 60B is an element that is utilized as a temperature sensor for measuring the ambient temperature. For the temperature measuring element 60B, a thermistor can be used, for example.

### Wire 70

A wire 70 is formed from a linear conductor having connection parts at both ends. In other words, a wire 70 has connection parts at both ends of the linear part to be connected to other constituent elements. A wire 70 is, for example, a metal wire. Examples of metals include gold, aluminum, silver, and copper.

### Lens Member 80

A lens member 80 has multiple lens shapes 83. The lens shapes are formed as separate parts that are isolated from one another. Each of the lens shapes 83 can have a lens flat face 81 and a lens face 82 located opposite the lens flat face 81. The lens member 80 collimates the incident light. In the example shown in FIG. 4 and FIG. 5, the lens member 80 has multiple lens shapes 83 each having a lens face 82. In this embodiment, each of the multiple lens faces 82 can have a different shape in accordance with the wavelength of the light that passes through the lens face. The lens member 80 can be formed from a light transmissive material, such as glass, plastic, or resin.

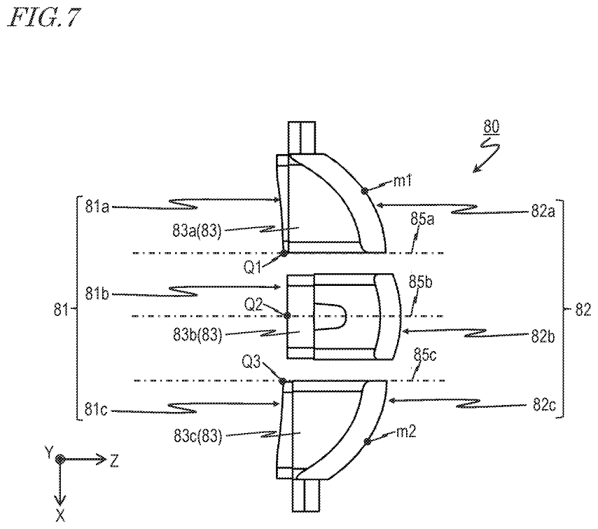

FIG. 7 is a top view showing an example of the structure of the lens member 80. FIG. 7 shows the structure example of a lens member 80 in which a plurality of lens shapes each having a lens face are formed and disposed as separate parts. The lens member 80 has three lens shapes. The lens member 80 has a first lens shape 83a which includes a first lens face 82a and a second lens shape 83b which includes a second lens face 82b provided on the same side as the first lens face 82a. As illustrated, the lens member 80 can further have a third lens shape 83c which includes a third lens face 82c provided on the same side as the first lens face 82a and the second lens face 82b. The first lens shape 83a, the second lens shape 83b, and the third lens shape 83c respectively have a first lens flat face 81a, a second lens flat face 81b, and a third lens flat face 81c. The second lens shape 83b is positioned between the first lens shape 83a and the third lens shape 83c. The first lens shape 82a, the second lens shape 82b, and the third lens shape 82c can each be a spherical or aspherical lens.

In the lens member 80 illustrated in FIG. 7, the first lens optical axis 85a of the first lens face 82a, the second lens optical axis 85b of the second lens face 82b, and the third lens optical axis 85c of the third lens face 82c are parallel. “Two lens optical axis being parallel” in this case includes the case in which they are not strictly parallel, allowing for a tolerance of up to +2°. In the top view, the first lens optical axis 85a and the third lens optical axis 85c overlap the respective lateral faces of their lens shapes that are located near the second lens shape 83b. The second lens optical axis 85b in the top view intersects the second lens face 82b. However, the paths of the first lens optical axis 85a and the third lens optical axis 85c are not limited to these, and can pass somewhere closer to or farther from the second lens shape than the respective lateral faces that are located near the second lens shape.

The first, second, and third lens shapes respectively have the first point Q1, second point Q2, and third point Q3 on the first lens flat face 81a, second lens flat face 81b, and third lens flat face 81c that are respectively located farthest from the first lens face 82a, second lens face 82b, and third lens face 82c in the Z direction. In the example shown in the drawing, the first point Q1, the second point Q2, and the third point Q3 are respectively positioned on the first lens optical axis 85a, the second lens optical axis 85b, and the third lens optical axis 85c. In relation to a direction normal to the lateral face of the first lens shape, i.e., the X direction, the first point Q1 is positioned closer to the second lens face 82b than the midpoint m1 of the first lens face 82a is. The third point Q3 is positioned closer to the second lens face 82b than the midpoint m2 of the third lens face 82c is. Here, the midpoint of a lens face is a point in the curved line constituting the outer edge of the lens face in the top view where the distance along the curved line from one end equals the distance from the other end.

In the lens member 80 illustrated in FIG. 7, the distance from the second point Q2 to the second lens face 82b in the Z direction is larger than the distance from the first point Q1 to the first lens face 82a and the distance from the third point Q3 to the third lens face 82c.

The lens member 80 is formed from a material having light transmissivity, and can be formed from, for example, a resin, glass, plastic or the like. When using a resin as the material, the lens member 80 can be formed by pouring the resin into a mold formed from a metal or plastic and hardening the resin. Using a resin as the material can increase the flexibility in shaping the lens member. Using a resin as the material can also improve the sphericity or asphericity of the lens.

### Beam Combiner 90

A beam combiner 90 outputs composite light by coaxially aligning multiple incident beams. The beam combiner 90 can have a structure in which multiple optical elements 91 are bonded. The optical elements 91 can be formed from a transparent material that transmits visible light, such as glass or plastic. The optical elements 91 can be achieved by using, for example, dichroic mirrors. A dichroic mirror can be formed from a multilayer dielectric film having predetermined wavelength selectivity. A multilayer dielectric film can be formed form Ta₂O₅/SiO₂, TiO₂/SiO₂, Nb₂O₅/SiO₂, or the like.

### Light Emitting Device 200

A light emitting device 200 will be explained next. In the description below, a light emitting device equipped with a package that houses multiple light emitting elements might be occasionally referred to as a “module.”

In the light emitting device 200 described as an example below, each of the light emitting elements 20 is an edge-emitting semiconductor laser element. The light emitting device 200 includes three light emitting elements 20. However, the number of light emitting elements is not limited to three, and may be four or more.

In the light emitting device 200 illustrated, multiple light emitting elements 20, a submount 30, an optical member 40, a light detector 50, multiple protective devices 60A, and a temperature measuring element 60B are disposed on the first mounting region 18a of the mounting face 11M of a substrate 11, and a first cap 16 surrounds the members that are disposed on the first mounting region 18a. The light emitting elements 20 are disposed on the first mounting region 18a via the submount 30. The light detector 50 is disposed on the first mounting region 18a, and the optical member 40 is disposed on the light receiving face of the light detector 50. The optical member 40 and the light detector 50 are disposed between the light emitting elements 20 and the first cap 16 at a position that crosses the light exiting from the light emitting elements 20. The light emitting elements and the other members disposed on the first mounting region are hermetically sealed by the substrate 11 and the first cap 16, or by the substrate 11, the second cap 120, and the lid 130. Hermetically sealing the space that houses the light emitting elements 20 can reduce the quality degradation attributable to dust accumulation.

The lower face of the submount 30 is boned to the mounting face 11M. The bonding face of the light detector 50 is bonded to the mounting face 11M. The submount 30 and the light detector 50 can be bonded to the mounting face 11M via a metal adhesive containing Au particles, for example.

Multiple wiring regions 14 electrically connected to at least one of the light emitting elements 20 can be provided in a region of the mounting face 11M located on one side or both sides of the submount 30 in the X direction. One or more protective devices 60A can be disposed in the first mounting regions 18a of the mounting face 11M. In the light emitting device 200 illustrated in FIG. 6, three protective devices 60A corresponding to the three light emitting elements 20 are disposed on the mounting face 11M.

A temperature measuring element 60B can be provided in the first mounting region 18a of the mounting face 11M. The temperature measuring element 60B is electrically connected to two wiring regions 14. In the example shown in FIG. 6, one of the pair of electrodes of the temperature measuring element 60B is electrically connected to one of the wiring regions 14. A wire 70 electrically connects the other of the pair of electrodes and the other wiring region 14.

The submount 30 is disposed on the first mounting region 18a of the mounting face 11M and supports the light emitting elements 20. The light emitting elements 20 are individually bonded to the upper face 30M of the submount 30 via a metal adhesive such as AuSn. At least one of the light emitting elements 20 is disposed such that its optical axis is oblique to the optical axis of an adjacent light emitting element as described later. The lower face of the submount 30 is bonded to the mounting face 11M via a metal adhesive, such as AuSn, Au particles, or the like.

One of the p-side and n-side electrodes of a light emitting element 20 is electrically connected to a wiring region disposed on the upper face 30M of the submount 30. One end of a wire 70 is electrically connected to the wiring region in the upper face 30M, and the other end of the wire 70 is electrically connected to one of a pair of wiring regions 14 disposed in the first mounting region 18a. One end of another wire 70 is electrically connected to the other of the p-side and n-side electrodes of the light emitting element 20, and the other end of the wire 70 is electrically connected to the other of the pair of wiring regions 14.

The first cap 16 is mounted on the mounting face 11M so as to surround the light emitting elements 20 and the other members disposed on the first mounting region 18a. The first cap 16 is bonded to the peripheral region 11P provided around the first mounting region 18a of the substrate 11. This forms a package 10 combining the substrate 11 and the first cap 16.

In the light emitting device 200 illustrated, the lens member 80 and the beam combiner 90 are disposed in the second mounting region 18b included in the mounting face 11M of the substrate 11. In the light emitting device 200 in FIG. 3, the lens member 80 and the beam combiner 90 are bonded to the substrate 11 via an adhesive. Examples of adhesives include UV-curable adhesives and thermosetting adhesives. Adhesives other than these may be used. In the Z direction, using the light emitting elements 20 as a reference, the lateral wall on which the light exiting from the light emitting elements 20 becomes incident will be referred to as the front side of the member, and the lateral wall opposite the incident-side lateral wall will be referred to as the rear side of the member. The light emitting elements 20, the package 10, the lens member 80, and the beam combiner 90 are disposed in that order from the rear side to the front side in the Z direction. The lens member 80 is disposed in front of the package 10 and receives the light exiting from the light emitting elements 20. The beam combiner 90 is disposed in front of the package 10, more forward than the lens member 80, and receives the light exiting from the lens member 80.

In a lateral side view when viewed in the Z direction, the emission point of the light emitting element 20 positioned farthest from the lid 130 does not overlap the lid 130. This can reduce the leakage of light from an unnecessary location.

How the light exiting from the light emitting elements advances will be explained with reference to FIG. 3, FIG. 4, or FIG. 5. In the example shown in the drawings, the light from each of the light emitting elements 20 enters the optical member 40. A portion of the light that entered the optical member 40 is reflected by the partially reflecting face and directed towards the light receiving region in the light receiving face of the light detector 50. The light incident on the light receiving region is utilized as the monitor light. Another portion of the light that entered the optical member 40 passes through the partially reflecting face and exits the member towards the lateral wall part 12 of the package 10. The light that has exited the optical member 40 is incident on the light incident face 10A of the lateral wall part. 12, passes through the light transmitting region, and exits through the light extraction face 10B. The light that has exited the light extraction face 10B is incident on the lens flat faces 81 of the lens member 80.

Furthermore, the multiple light beams collimated by the lens member 80 are incident on the beam combiner 90. The light beams are coaxially combined and the composite light exits the beam combiner 90. The composite light exiting from the beam combiner 90 passes through the incident face of the lid 130 and exits through the emission face of the lid 130 to the outside of the light emitting device 200.

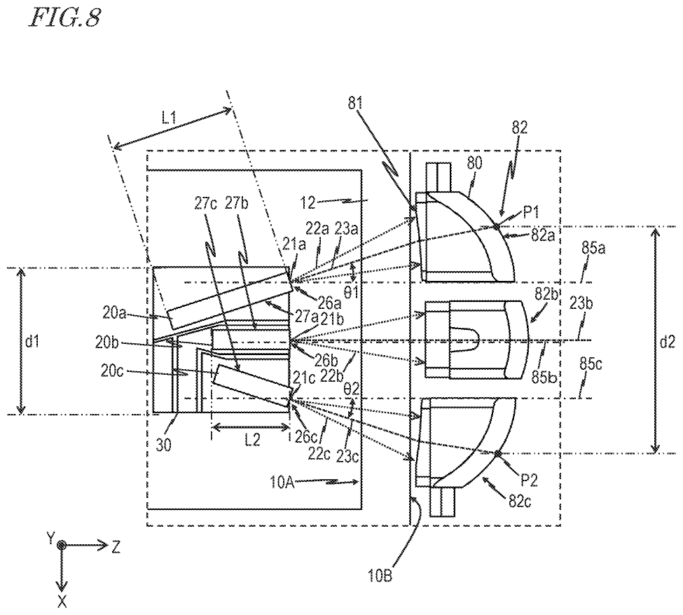

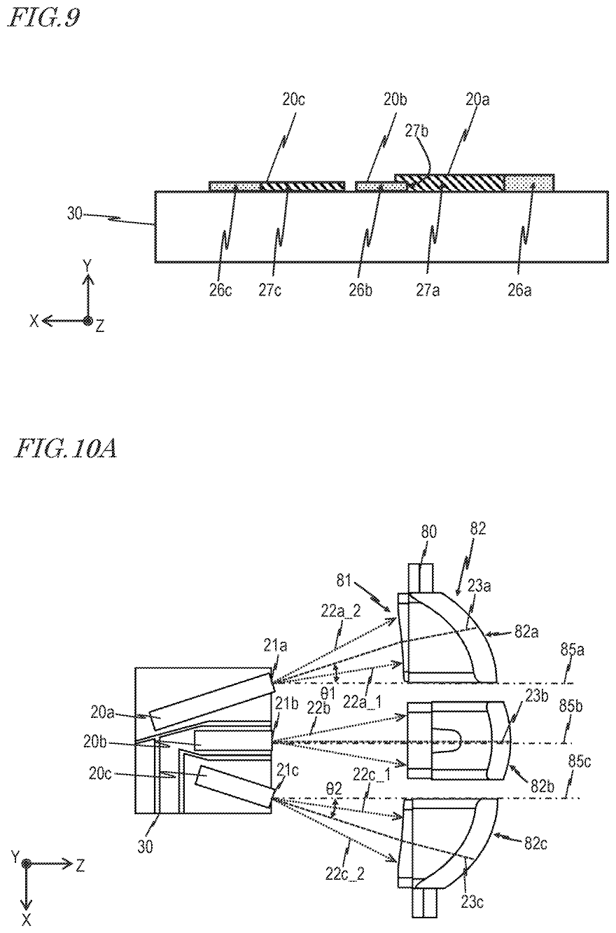

FIG. 8 is a schematic diagram showing how the light exiting from each light emitting element 20 passes through the light incident face 10A and the light extraction face 10B of the package 10 to be incident on the lens member 80. In FIG. 8, the main portions of the light exiting from the light emitting elements 20 are indicated by dotted arrows. The optical axis of the light from each light emitting element 20 is indicated by a dotted line. The optical axis of each of the lens faces included in the lens faces 82 of the lens member 80 is indicated by a one-dot-chain line. FIG. 9 is a schematic diagram showing the emission end faces and the lateral faces of the light emitting elements 20 mounted on the submount 30 in a lateral side view when viewed in the Z direction.

The light emitting elements 20 in this embodiment include a first light emitting element 20a, a second light emitting element 20b, and a third light emitting element 20c, each emitting light of a peak emission wavelength different from one another. However, the light emitting elements 20 may include two or more light emitting elements which emit light of the same peak emission wavelength.

The first light emitting element 20a has a first emission end face 26a where the first emission point 21a is located, and a first lateral face 27a meeting the first emission end face 26a and located on the second light emitting element 20b side. The first light emitting element 20a emits first light 22a having an emission peak at a first wavelength from the first emission point 21a along the first optical axis 23a. The second light emitting element 20b has a second emission end face 26b where the second emission point 21b is located, and a second lateral face 27b meeting the second emission end face 26b and positioned on the first light emitting element 20a side. The second light emitting element 20b emits second light 22b having an emission peak at a second wavelength from the second emission point 21b along the second optical axis 23b. The third light emitting element 20c has a third emission end face 26c where the third emission point 21c is located, and a third lateral face 27c meeting the third emission end face 26c and located on the second light emitting element 20b side. The third light emitting element 20c emits third light 22c having an emission peak at a third wavelength from the third emission point 21c along the third optical axis 23c.

In this embodiment, the first wavelength is longer than the second wavelength, and the second wavelength is longer than the third wavelength. For example, the first light 22a is red light, the second light 22b is green light, and the third light 22c is blue light. However, the first light 22a, the second light 22b, and the third light 22c can be light of a color different from one another selected from red, green, and blue light. Light other than visible light may be included.

In the light emitting device 200 in this embodiment, two adjacent light emitting elements 20 can be disposed on the submount 30 such that one is oblique to the other. In the example shown in FIG. 8, the first light emitting element 20a and the third light emitting element 20c are disposed to be oblique to the second light emitting element 20b.

In the top view, the three light emitting elements 20a, 20b, and 20c are disposed such that their emission points align on a side of the submount 30 extending in parallel with the X direction. In the X direction, the second light emitting element 20b is located between the first light emitting element 20a and the third light emitting element 20c. The second light emitting element 20b is disposed such that the second optical axis 23b is in parallel with the Z direction. Being parallel here includes a tolerance of up to +2°. The first light emitting element 20a is disposed such that the first optical axis 23a is oblique to the second optical axis 23b. The third light emitting element 20c is disposed such that the third optical axis 23c is oblique to the second optical axis 23b. In this layout, the first optical axis 23a and the second optical axis 23b are nonparallel, and the third optical axis 23c and the second optical axis 23b are nonparallel.

In the present specification, the term “parallel” in relation to two optical axes can include the case in which the angle formed by the two optical axes is not strictly 0°. Even in such a case, however, the angle formed by the two optical axes is not 3° or greater. The term “nonparallel” means that the angle formed by two optical axes is 3° or greater.

The first light 22a, the second light 22b, and the third light 22c respectively emitted from the emission points of the light emitting elements 20a, 20b, and 20c are incident on the light incident face 10A of the lateral wall part 12 having light transmissivity. The first light 22a, the second light 22b, and the third light 22c which are incident on the light incident face 10A exit through the light extraction face 10B towards the front of the package 10.

With respect to the optical paths of the light beams from the light emission points 21 until they enter the lens faces 82, the first interval between the first optical axis 23a and the second optical axis 23b increases as the first light 22a and the second light 22b respectively travel along the first optical axis 23a and the second optical axis 23b. Similarly, the second interval between the second optical axis 23b and the third optical axis 23c increases as the second light 22b and the third light 22c respectively travel along the second optical axis 23b and the third optical axis 23c. The first interval and the second interval may increase even in the optical paths past the lens faces 82.

In a top view when viewed in the Y direction, the angle formed by the first optical axis 23a and the second optical axis 23b is designated as θ1. The angle θ1 matches the oblique angle of the first light emitting element 20a to the second light emitting element 20b. Similarly, in the top view when viewed in the first direction, the angle formed by the second optical axis 23b and the third optical axis 23c is designated as θ2. The angle θ2 matches the oblique angle of the third light emitting element 20c to the second light emitting element 20b.

The lens member 80 includes a first lens shape which has a first lens face 82a located on the side that faces the package 10 or the side located opposite the side facing the package 10, and a second lens shape which includes a second lens face 82b located on the same side as the first lens face 82a. The lens member 80 can further have a third lens shape which includes a third lens face 82c located on the same side as the first lens face 82a and the second lens face 82b. The lens member 80 illustrated in FIG. 8 has a first lens shape, a second lens shape, and a third lens shape located opposite the faces facing the package 10 or the submount 30. The lens faces 82 include the first lens face 82a, second lens face 82b, and third lens face 82c. The first to third lens shapes are formed as separate lenses.

As illustrated in FIG. 8, the first emission point 21a of the first light emitting element 20a is positioned on the first lens optical axis 85a of the first lens face 82a. The second emission point 21b of the second light emitting element 20b is positioned on the second lens optical axis 85b of the second lens face 82b. The third emission point 21c of the third light emitting element 20c is positioned on the third lens optical axis 85c of the third lens face 82c. Positioning the emission points on the lens optical axes allows the light entering the lenses to exit the lens faces as the light parallel to the lens optical axes. There might be a case in which each emission point is not strictly positioned on the respective lens optical axis. Even in such a case, however, the tolerance does not exceed 0.1 mm. At least the main portion of the first light 22a passes through the first lens face 82a. At least the main portion of the second light 22b passes through the second lens face 82b. At least the main portion of the third light 22c passes through the third lens face 82c.

Because the lens member 80 has individually formed multiple lens shapes, the layout can be flexibly changed in accordance with the oblique angles of the light emitting elements. The first to third lens shapes can be disposed such that the main portions of the first to third light respectively pass through the first to third lens faces in accordance with the package size and the obliqueness of the light emitting elements. With respect to the lens member 80, in the X direction, the distance from the straight line connecting the first point Q1 and the first emission point 21a to the second lens shape and the distance from the straight line connecting the third point Q3 and the third emission point 21c to the second lens shape are respectively smaller than the distance from the midpoint m1 of the first lens face to the second lens shape and the midpoint m2 of the third lens face to the second lens shape. Using a lens member 80 shaped in this manner makes it possible to dispose multiple light emitting elements 20 so as to reduce the distance between the emission points.

In the example shown in FIG. 8, the first lens optical axis 85a, the second lens optical axis 85b, and the third lens optical axis 85c are parallel. The second lens optical axis 85b and the second optical axis 23b are parallel, but the first lens optical axis 85a and the first optical axis 23a are nonparallel, and the third lens optical axis 85c and the third optical axis 23c are nonparallel. The angle formed by the second lens optical axis 85b and the first optical axis 23a matches the angle θ1, and the angle formed by the second lens optical axis 85b and the third optical axis 23c matches the angle 62.

An example of the range for each of the angles θ1 and θ2 can be 3° to 45°. Setting these angles to 3° or greater can achieve the disposition of the light emitting elements with reduced distances between adjacent emission points without allowing the main portions of the first light 22a, the second light 22b, and the third light 22c to interfere with one another in the optical paths from the emission points to the light incident face 10A of the package. This can reduce the size of the package 10 in the X direction. Setting these angles to 45° at most can facilitate the disposition of the light emitting elements 20 so as not to come in contact with one another. This also can make the overall package of the lens member 80 smaller than the overall size of the package 10 in the X direction.

The angle range for the angles θ1 and θ2 is more preferably set to 5° to 30°. Setting these angles to 5° or greater can make it harder for the maim portions of the light from adjacent light emitting elements to interfere with one another even in the case of using light emitting elements which emit light having large divergence angles. This can thus make it possible to dispose multiple light emitting elements 20 while reducing the distance between emission points of adjacent light emitting elements, thereby reducing the size of the package 10 in the X direction. Because the lens member 80 disposed on the outside of the package 10 allows the light spreading in accordance with the distance from the emission point to pass through, the size in the X direction cannot be reduced like the distance between adjacent emission points. Setting each of the angles θ1 and θ2 to 5° or greater allows the divergent light to enter the lens member 80 which is larger in size in the X direction than the distance between adjacent emission points even when the distance between emission points are made smaller.

Setting the angles to 30° or smaller can reduce the X-direction size of the light incident face 10A of the lateral wall part 12 on which the light from multiple light emitting elements 20 is incident, thereby reducing the size of the package 10. This can also reduce the impact of the spherical aberrations that occur when the first light and the third light pass through the first lens face 82a and the third lens face 82c.

The point of intersection of the first lens face 82a and the first optical axis 23a is designated as point P1, and the point of intersection of the third lens face 82c and the third optical axis 23c is designated as point P2. In the example shown in FIG. 8, when assuming the length of the side of the submount 30 where the upper face meets the lateral face opposing the light incident face 10A as the length d1, the length d1 in the X direction is smaller than the length d2 of the straight line connecting the points P1 and P2 in the X direction. The length d2 can be, for example, about 2 mm. Setting the length d1 of the submount 30 as described above can reduce the X-direction size of the package 10 in which multiple wiring regions 14 are provided on one side or both sides of the submount 30.

In the example shown in FIG. 9, in a direction normal to the second emission end face 26b of the second light emitting element 20b, i.e., in a plan view when viewed in the Z direction, a portion of the first lateral face 27a of the first light emitting element 20a overlaps the second emission end face 26b of the second light emitting element 20b in whole or part. On the other hand, the third lateral face 27c of the third light emitting element 20c does not overlap the second emission end face 26b of the second light emitting element 20b.

The length L1 of the first lateral face 27a in the direction perpendicular to the first emission end face 26a of the first light emitting element 20a is larger than the length L2 of the second lateral face 27b in the direction perpendicular to the emission end face 26b of the second light emitting element 20b. As described above, in the example illustrated, the length of the first light emitting element 20a which emits red light is larger than the lengths of the second light emitting element 20b which emits green light or the third light emitting element 20c which emits blue light. However, the relationship among the lengths of the light emitting elements is not limited to this example. By adjusting the lengths of the light emitting elements, the laser light output can be adjusted.

In the case in which the length L2 of the second light emitting element 20b is smaller than the length L1 of the first light emitting element 20a, the light emitting elements can be disposed such that the first optical axis 23a is oblique to the second optical axis 23b without allowing the first light emitting element 20a and the second light emitting element 20b to come into contact with one another. Allowing for such a disposition can reduce the overall length of the light emitting elements in the Z direction to thereby reduce the Z-direction length of the submount 30 on which the light emitting elements are disposed. Setting the length L2 smaller than the length L1 allows for the disposition of the light emitting elements such that the emission end face of the first light emitting element 20a partly overlaps the lateral face of the second light emitting element 20b in a lateral side view when viewed in the Z direction. Such a disposition can reduce the overall length of the light emitting elements in the X direction, thereby reducing the length of the submount 30 in the X direction.

FIG. 10A is a schematic diagram showing an example of how the first light 22a traveling along the first optical axis 23a spreads in the optical path until it enters the lens member 80. FIG. 10B is a schematic diagram showing another example of how the first light 22a traveling along the first optical axis 23a spreads in the optical path until it enters the lens member 80.

The first light 22a, the second light 22b, and the third light 22c respectively have a first beam shape, a second beam shape, and a third beam shape that are defined by far field patterns. In other words, a beam shape is defined by the main portion of the light emitted by a light emitting element 20. There is a peripheral portion of the light around the beam shape. The first light 22a, the second light 22b, and the third light 22c each have a first boundary, a second boundary, and a third boundary that define the first beam shape, the second beam shape, and the third beam shape.

The first boundary that defines the first beam shape of the first light 22a includes two border lines in a top view. The one of the two border lines that is closer to the second optical axis 23b of the second light 22b is marked as a border line 22a_1, and the one farther from the second optical axis 23b is marked as a border line 22a_2 in order to distinguish one from the other for explanation purposes. Similarly, the one of the two border lines of the third boundary that is closer to the second optical axis 23b is marked as border line 22c_1 and the one farther from the second optical axis 23b is marked as border line 22c_2.

The oblique angle 61 of the first light emitting element 20a to the second light emitting element 20b can be adjusted such that the interval between the border line 22a_1 of the first beam shape and the second optical axis 23b remains constant or increases as the first light 22a travels along the first optical axis 23a in the optical paths of the first light 22a, the second light 22b, and the third light 22c until they enter the lens member 80. Similarly, the oblique angle θ2 of the third light emitting element 20c to the second light emitting element 20b can be adjusted such that the interval between the border line 22c_1 of the third beam shape and the second optical axis 23b remains constant or increases as the third light 22c travels along the third optical axis 23c.

In the example shown in FIG. 10A, the interval between the border line 22a_1 of the first beam shape and the second optical axis 23b increases as the first light 22a travels along the first optical axis 23a. In this case, the oblique angle θ1 of the first light emitting element 20a is larger than the divergence angle of the first light 22a. In the example shown in FIG. 10B, the interval between the border line 22a_1 of the first beam shape and the second optical axis 23b remains constant as the first light 22a travels along the first optical axis 23a. The light coinciding with the border line 22a_ 1 travels along the first lens optical axis 85a of the first lens face 82a in parallel with the second optical axis 23b. In this case, the oblique angle θ1 of the first light emitting element 20a is equal to the divergence angle of the first light 22a. The two angles being equal can technically include a small tolerance. Even in such a case, the tolerance is +1° at most. Setting the oblique angle θ1 to be equal to or greater than the divergence angle of the first light 22a can achieve a structure which provides a space between the border line 22a_1 of the first beam shape and the second light 22b in the optical paths of the light beams until they enter the first lens shape 83a and the second lens shape 83b, respectively. Positioning the first light emitting 20a to be oblique to achieve such a structure can reduce the distance between the emission points of the adjacent light emitting elements.

Similarly, in the example shown in FIG. 10A, the interval between the border line 22c_1 of the third beam shape and the second optical axis 23b increases as the third light 22c travels along the third optical axis 23c. In this case, the oblique angle of the third light emitting element 20c is larger than the divergence angle of the third light. In the example shown in FIG. 10B, the interval between the border line 22c_1 of the third beam shape and the second optical axis 23b remains constant as the third light 22c travels along the third optical axis 23c. The light coinciding with the border line 22c_1 travels along the third lens optical axis 85c of the third lens face 82c in parallel with the second optical axis 23b. In this case, the oblique angle of the third light emitting element 20c is equal to the divergence angle of the third light.

### Light Emitting Element Layout Variations

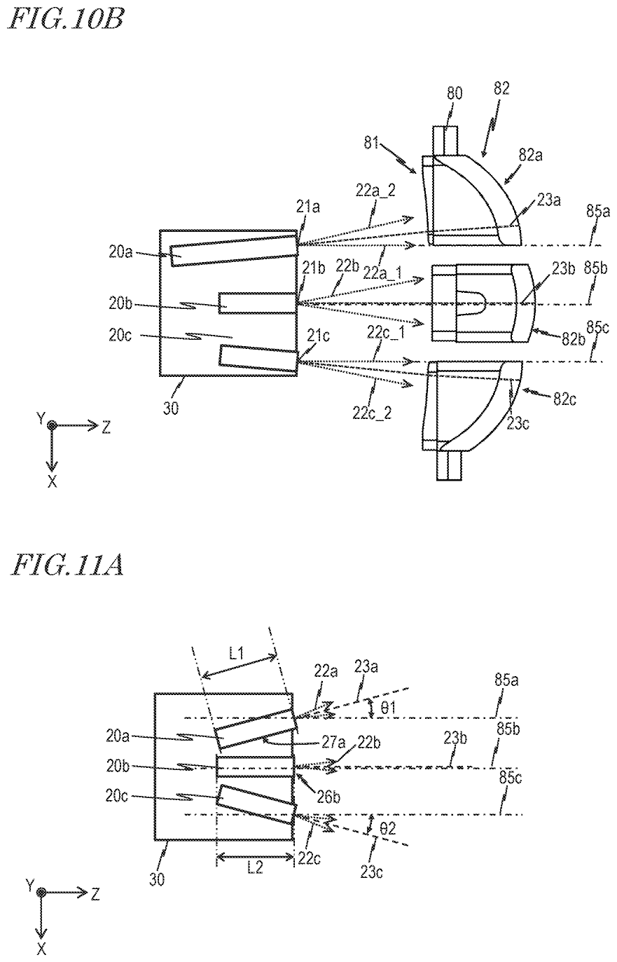

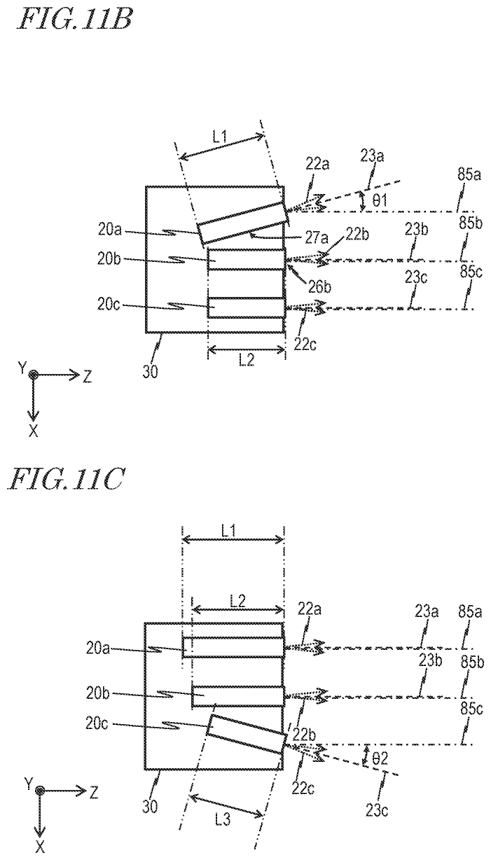

FIG. 11A to FIG. 11C are schematic diagrams showing first to third variations of the layout of the light emitting elements 20 on the submount 30. The first variation shown in FIG. 11A will be explained first.

In a lateral side view when viewed in the Z direction, the first lateral face 27a of the first light emitting element 20a does not overlap the second emission end face 26b of the second light emitting element 20b. In this example, the length L1 of the first light emitting element 20a is substantially equal to the length L2 of the second light emitting element 20b. The length of the third light emitting element 20c is substantially equal to the length L2 of the second light emitting element 20b.

FIG. 11B is a schematic diagram of the second variation of the layout of the light emitting elements 20. The length L1 of the first light emitting element 20a is larger than the length L2 of the second light emitting element 20b. However, the first lateral face 27a of the first light emitting element 20a does not overlap the second emission end face 26b of the second light emitting element 20b in a lateral side view when viewed in the Z direction.

The first optical axis 23a is nonparallel to the second optical axis 23b. The angle θ1 formed by the first optical axis 23a and the second optical axis 23b can be, for example, 3° to 45°. On the other hand, the third optical axis 23c is in parallel with the second optical axis 23b.

FIG. 11C is a schematic diagram of the third variation of the layout of the light emitting elements 20. The length L1 of the first light emitting element 20a is larger than the length L2 of the second light emitting element 20b, and the length L2 is larger than the length L3 of the third light emitting element 20c. The difference in length between the first light emitting element 20a and the second light emitting element 20b (L1-L2) is relatively smaller, and the difference in length between the second light emitting element 20b and the third light emitting element 20c (L2-L3) is relatively larger. The third light emitting element 20c which has a relatively larger difference in length from the second light emitting element 20b is oblique to the second light emitting element, and the angle θ2 formed by the second optical axis 23b and the third optical axis 23c is 3° to 45°. The first optical axis 23a of the first light emitting element 20a and the second optical axis 23b of the second light emitting element 20b are parallel.

### Disposing Four Light Emitting Elements

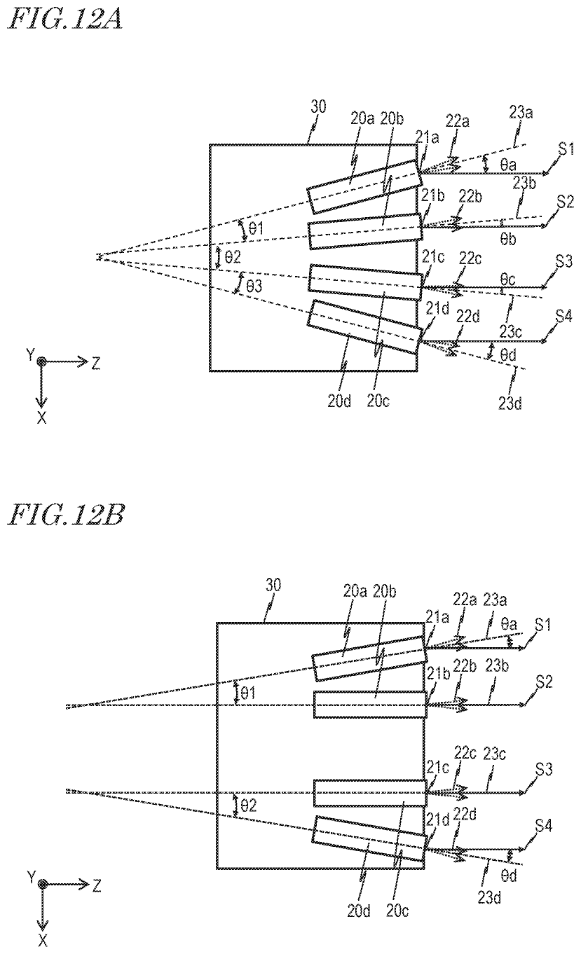

The light emitting device 200 according to this embodiment can include four or more light emitting elements 20. FIG. 12A is a schematic diagram showing an example of the layout of four light emitting elements 40 disposed on the submount 30. FIG. 12B is a schematic diagram showing another example of the layout of four light emitting elements 40 disposed on the submount 30. In FIG. 12A and FIG. 12B, solid line arrows S1 to S4 parallel to the Z direction are provided.

In the layout illustrated in FIG. 12A or FIG. 12B, the four light emitting elements 20 include a fourth light emitting element 20d. The fourth light emitting element 20d emits fourth light 22d having an emission peak at a fourth wavelength from the fourth emission point 21d along the fourth optical axis 23d. The fourth wavelength is different from the first wavelength, the second wavelength, and the third wavelength. For example, the first light 22a, the second light 22b, the third light 22c, and the fourth light 22d are respectively infrared light, red light, green light, and blue light. However, the first light 22a, the second light 22b, the third light 22c, and the fourth light 22d can each be light having a different peak wavelength from one another selected from infrared, red, green, and blue light.

The first light emitting element 20a, the second light emitting element 20b, the third light emitting element 20c, and the fourth light emitting element 20d are mounted on the mounting face 11M of the substrate 11 in the state of being supported by the submount 30. In a top view, the emission points of the first light emitting element 20a, the second light emitting element 20b, the third light emitting element 20c, and the fourth light emitting element 20d are aligned on a side of the submount 30 extending in parallel with the X direction.

In the example shown in FIG. 12A, the first light emitting element 20a is disposed to be oblique to the arrow S1. The second light emitting element 20b is disposed to be oblique to the arrow S2. The third light emitting element 20c is disposed to be oblique to the arrow S3. The fourth light emitting element 20d is disposed to be oblique to the arrow S4. As for the angle ranges for the angle θa formed by the first optical axis 23a and the arrow S1, the angle θb formed by the second optical axis 23b and the arrow S2, the angle θc formed by the third optical axis 23c and the arrow S3, and the angle θd formed by the fourth optical axis 23d and the arrow S4, similar conditions to those for the angle θ1 in the form in which three light emitting elements according to this embodiment are disposed can apply. In the example shown in FIG. 12A, the angle θb is preferably smaller than the angle θa, and the θc is preferably smaller than the angle θd. Disposing the light emitting elements to achieve the angles described above can make it hard for the main portions of the light from adjacent light emitting elements to interfere with one another while reducing the distance between the emission points of the light emitting elements. For example, the light emitting elements may be disposed such that the angle θa equals the angle θd and the angle θb equals the angle θc.

The angle θ1 formed by the first optical axis 23a and the second optical axis 23b equals the difference between the angle θa and the angle θb in absolute value. The angle θ2 formed by the second optical axis 23b and the third optical axis 23c equals the sum of the angle θb and the angle θc. Here, the angle formed by the third optical axis 23c and the fourth optical axis 23d in a top view is marked as angle θ3. The angle θ3 equals the difference between the angle θc and the angle θd in absolute value. As for the angle ranges for the angles θ1, θ2, and θ3, similar conditions to those for the angles θa to θd can apply.

With respect to the optical paths of the light beams from the four light emitting elements 20 to the light incident face 10A, the first interval between the first optical axis 23a and the second optical axis 23b increases as the first light 22a and the second light 22b respectively travel along the first optical axis 23a and the second optical axis 23b. The second interval between the second optical axis 23b and the third optical axis 23c increases as the second light 22b and the third light 22c respectively travel along the second optical axis 23b and the third optical axis 23c. Because the fourth optical axis 23d is oblique to the third optical axis 23c forming an angle θ3, the third interval between the third optical axis 23c and the fourth optical axis 23d increases as the third light 22c and the fourth light 22d respectively travel along the third optical axis 23c and the fourth optical axis 23d.

Even when the light emitting elements 20 include four light emitting elements, in a lateral side view when viewed in the Z direction, a portion of the lateral face of the first light emitting element 20a may overlap a portion of the emission end face of the second light emitting element 20b. Furthermore, a portion of the lateral face of the fourth light emitting element 20d may overlap a portion of the emission end face of the third light emitting element 20c.

In the example shown in FIG. 12B, the first light emitting element 20a is disposed to be oblique to the arrow S1 to form an angle θa. The second light emitting element 20b is disposed in parallel with the arrow S2. The third light emitting element 20c is disposed in parallel with the arrow S3. The fourth light emitting element 20d is disposed to be oblique to the arrow S4 to form an angle θd. As for the angle ranges for the angles θ1 and θ2, similar conditions to those for the angle θ1 shown in FIG. 12A can apply.

Isolating the second light emitting element 20b and the third light emitting element 20c in the X direction creates a space between the second light emitting element 20b and the third light emitting element 20c on the submount 30. For example, a wiring region to be electrically connected to the light emitting elements 20 can be provided in this space.

### Second Embodiment

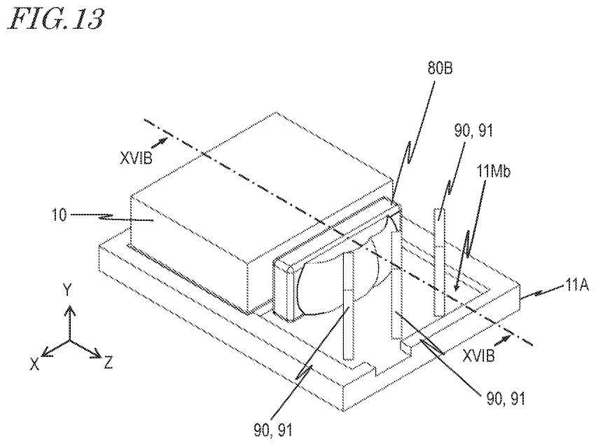

Other variations of the lens member of this embodiment will be explained with reference to FIG. 13 to FIG. 16B. The light emitting device 300 according to a second embodiment differs from the light emitting device 200 according to the first embodiment by having an integrally formed lens member 80A or 80B, and a substrate 11A.

### Lens Member 80A

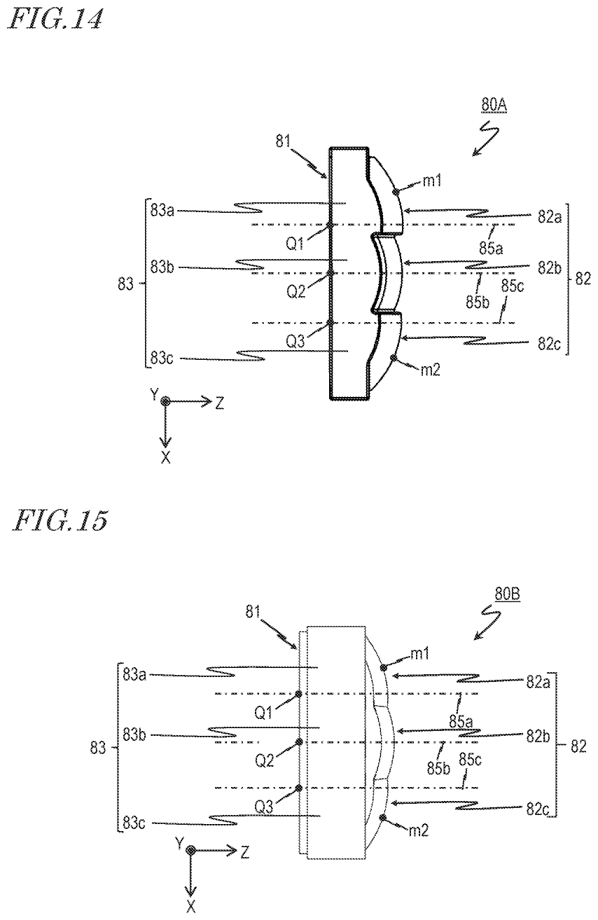

FIG. 14 is a top view showing an example of the structure of an integrally formed lens member 80A. In the lens member 80A illustrated in the drawing, the first lens shape 83a to the third lens shape 83c are connected. The lens member has a single lens flat face 81 and three lens faces 82a to 82c. The lens member 80A can be formed from a material having light transmissivity. The material can be the same as that for the lens member 80 as an example. The lens member 80A will be described below while omitting the common features explained with reference to the lens member 80.

The first lens shape 83a to the third lens shape 83c in the lens member 80A are connected. In a top view when viewed in the Y direction, the first lens optical axis 85a, the second lens optical axis 85b, and the third lens optical axis 85c respectively pass the first lens face 82a, the second lens face 82b, and the third lens face 82c. In the Z direction, the distance from the second point Q2 to the second lens face 82b can be the same as the distance from the first point Q1 to the first lens face 82a and the distance from the third point Q3 to the third lens face 82c. The term “same” as used here includes a tolerance of +2 mm. Similar to the lens member 80, the first point Q1 is positioned closer to the second lens face 82b than the midpoint m1 of the first lens face 82a is in the X direction. Similarly, the third point Q3 is positioned closer to the second lens face 82b than the midpoint m2 of the third lens face 82c is.

### Lens Member 80B

FIG. 15 is a top view of another example of an integrally formed lens member. Similar to the lens member 80A, the lens member 80B shown in the drawing, in which the first lens shape 83a to the third lens shape 83c are connected, has a single lens flat face 81 and three lens faces 82a to 82c. The lens member 80B will be described below while omitting the common features described with reference to the lens member 80A as appropriate.

The distance from the second point Q2 to the second lens face 82b in the second direction is larger than the distance from the first point Q1 to the first lens face 82a and the distance from the third point Q3 to the third lens face 82c. Such a lens structure can give the lens member a shape that is close to an arc of a circle, thereby improving the ease of integrally forming multiple lens shapes.

### Substrate 11A

The substrate 11A has, in its upper face, a mounting face 11M including a first mounting face 11Ma and a second mounting face 11Mb. The first mounting face 11Ma is located higher than the second mounting face 11Mb. In other words, there is a level difference between the first mounting face 11Ma and the second mounting face 11Mb. A first mounting region 18a is provided in the first mounting face 11Ma, and a second mounting region 18b is provided in the second mounting face 11Mb. In the substrate 11A, the first mounting region 18a and the peripheral region 11P are provided on the same first mounting face 11Ma.

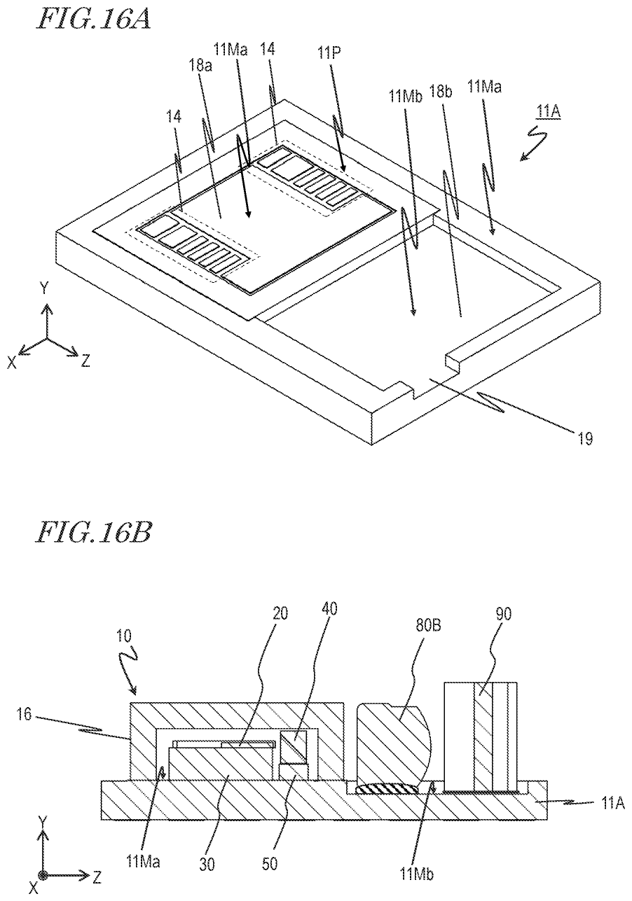

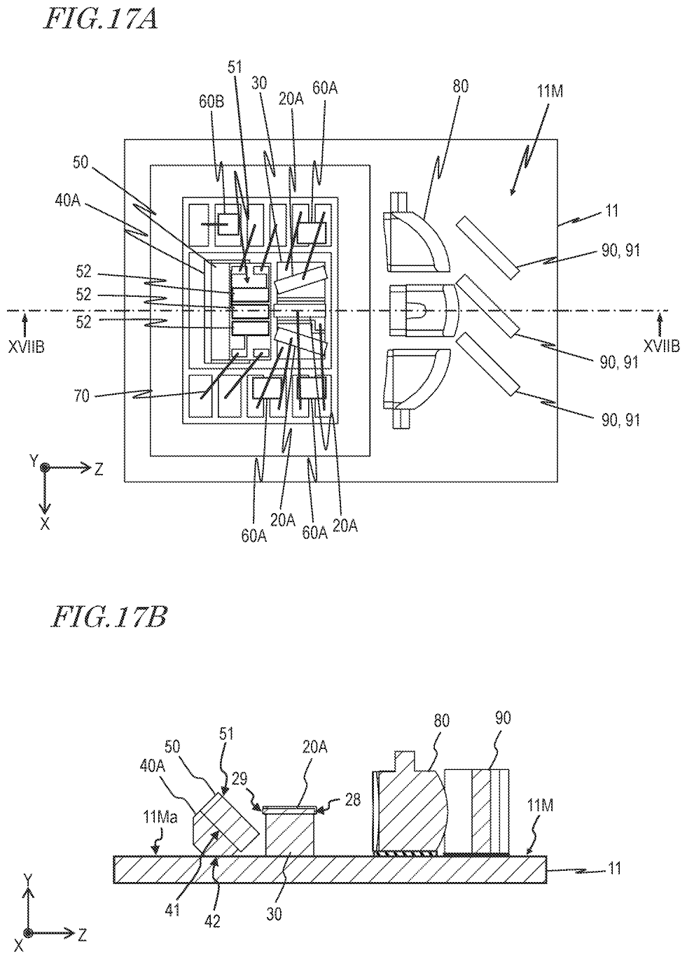

The substrate 11A, similar to the substrate 11 in the first embodiment, has a flat-plate shape. In a top view, the outline of the substrate 11A is rectangular. The first mounting face 11Ma can enclose the second mounting face 11Mb entirely or partly. The first mounting face 11Ma of the substrate 11A illustrated in FIG. 16A partly encloses the second mounting face 11Mb. An opening 19 is created where the second mounting face 11Mb is not enclosed by the first mounting face 11Ma attributable to the level difference between the first mounting face 11Ma and the second mounting face 11Mb. The opening 19 is provided on the side opposite the package 10 while interposing the second mounting face 11Mb.

The opening 19 illustrated in FIG. 16A is recess shaped in a lateral side view when viewed in the Z direction. The width of the opening 19 in the X direction can be one half of the X-direction width of the substrate 11A or smaller. The opening 19 can be provided at a position not overlapping the imaginary straight line which halves the lateral face of the substrate 11A in the X direction. In the example shown, the opening 19 is located on the right side of the imaginary straight line.

The substrate 11A can be formed from a similar material to that for the substrate 11. The substrate 11A can be formed from a ceramic as a main material, for example. The substrate 11A can be formed from a light shielding material that blocks light. For example, the substrate 11A can be formed from a light shielding ceramic as a main material.

### Light Emitting Device 300

A light emitting device 300 will be explained next. FIG. 13 is a perspective view of the light emitting device 300 which includes a substrate 11A, and a lens member 80B disposed on the second mounting face 11Mb. FIG. 16A is a perspective view illustrating the structure of the substrate 11A. FIG. 16B is a cross-sectional view of the light emitting device 300 taken along line XVIB-XVIB in FIG. 13. On the second mounting face 11Mb, a lens member 80A may be disposed. In the example shown in FIG. 16B, which is a cross section of the light emitting device 300, the lens member 80 and the beam combiner 90 are disposed on the second mounting face 11Mb which is lower positioned than the first mounting face 11Ma. Such a layout can bring the heights of the lens member 80 and the beam combiner 90 in the Y direction close to the height of the package 10 in the Y direction. This, as a result, can reduce the size of the light emitting device 300 in the Y direction which corresponds to the height direction.

### Third Embodiment

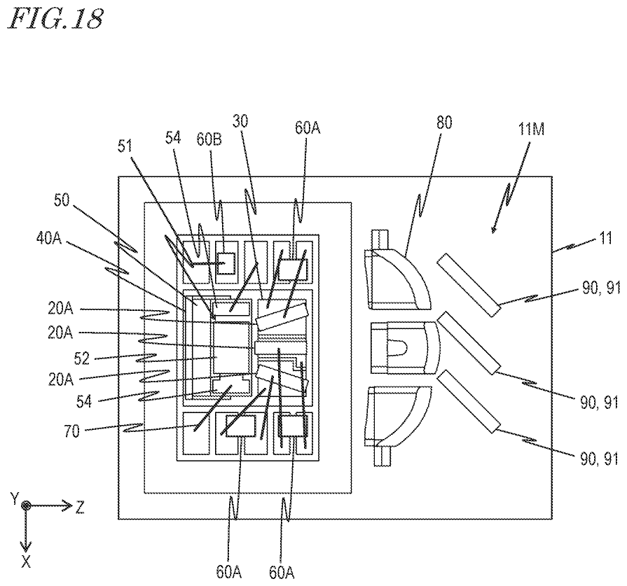

A light emitting device 400 according to a third embodiment will be explained with reference to FIG. 1, FIG. 17A, and FIG. 17B. The light emitting device 400 according the third embodiment differs from the light emitting device 200 according to the first embodiment or the light emitting device 300 according to the second embodiment by including light emitting elements 20A and a support 40A in place of the light emitting elements 20 and the optical member 40, and positioning the light detector 50 disposed on the support 40A on the side opposite the emission end faces of the light emitting elements 20A.

FIG. 1 is a perspective view of the light emitting device 400. FIG. 17A is a top view of the light emitting device 400 from which the second cap 120, the lid 130, and the first cap are removed. FIG. 17B is a cross-sectional view taken along line XVIIB-XVIIB in FIG. 17A.

Each constituent element will be explained. The differences from the light emitting device 200 of the first embodiment or the light emitting device 300 of the second embodiment will be primarily described while omitting the common features as appropriate. The first cap of the light emitting device 400 of the third embodiment is a member equivalent to the first cap 16 of the light emitting device 100 of the first embodiment.

### Light Emitting Element 20A

The light emitting device 400 according to the third embodiment includes light emitting elements 20A. The light emitting elements 20A are, for example, semiconductor laser elements. Each light emitting element 20A emits light from both the emission end face 28 and the opposing face 29 located opposite the emission end face 28. The intensity of the light emitted from the emission end face 28 is higher than the intensity of the light emitted from the opposing face 29. Specifically, the amount of light that exits the emission end face 28 is 90% or more of the total amount of the light exiting from the emission end face 28 and the opposing face 29, and the amount of light that exits the opposing face is less than 10%, for example.

### Support 40A

The support 40A is a member having an oblique face. The support 40A has a lower face 42 and an oblique face which is oblique to the lower face 42 and functions as a support face. The support face 41 illustrated in FIG. 17B is a flat face that is oblique to the lower face 42 at a certain oblique angle. The oblique angle is in the range of 10° to 80°, for example, preferably in the range of 40° to 50°. In the light emitting device 400 illustrated, the support face 41 is oblique to the lower face 42 forming a 45° oblique angle. The support face can include one or more oblique faces. In such a case, the one having the largest area among all oblique faces serves as the support face 41.

The support 40 can be formed from, for example, a ceramic, glass, or metal. For example, ceramics such as aluminum nitride, glass such as quartz or borosilicate glass, or metals such as aluminum can be used. Alternatively, the support 40 can be formed from silicon or the like.

### Light Emitting Device 400

A light emitting device 400 will be explained. The support 40A is disposed on the first mounting face 11Ma of the substrate 11. Furthermore, a light detector 50 is disposed on the support face 41 of the support 40A. In the first mounting face 11Ma, the light emitting elements 20A are positioned closer to the light incident face than the support 40A and the light detector 50 are. In the example shown in FIGS. 17A and 17B, the light emitting elements 20A are positioned farther on the positive side of the Z axis (the direction pointed by the Z axis arrow) than the support 40A and the light detector 50 are. The support face 41 of the support 40A and the light receiving face 51 of the light detector 50 face the opposing faces 29 of the light emitting elements 20A.

The lights exiting from the emission end faces 28 of the light emitting elements 20A advances towards the light incident face, i.e., in the positive direction of the Z axis. The lights exiting from the opposing faces 29 advances to the opposite side of the light incident face, i.e., in the negative direction of the Z axis (the direction not pointed by the Z axis arrow). The light exiting from each of the opposing faces 29 are incident on the corresponding light receiving region 52 provided in the light receiving face 51 of the light detector 50. Positioning the light emitting elements 20A closer to the light incident face than the support 40A and the light detector 50 are as described above can bring the emission end faces 28 even closer to the light incident face. This can reduce the distance of travel of the exiting divergent light from each light emitting element 20A to the light incident face. In other words, each of the light emitting elements 20A can be positioned closer to the lens member 80 than the support 40A and the light detector 50 are. This can reduce the distance of travel of the divergent light from each light emitting element 20A to the incident face of the lens member 80.

### Light Emitting Device 401

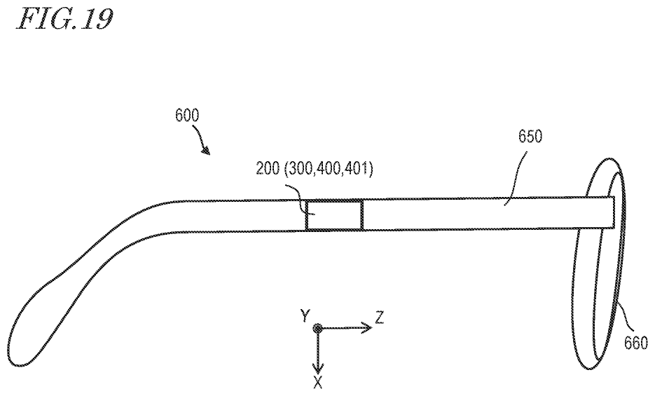

A variation of the light emitting device according to the third embodiment will be explained next with reference to FIG. 18. FIG. 18 is a top view of a light emitting device 401 from which the second cap 120, the lid 130, and the first cap are removed. Similar to the light emitting device 400, the first cap is an equivalent member to the first cap 16 of the light emitting device 100. FIG. 1 is a perspective view of the light emitting device 401. The light emitting device 401 includes a light detector 50 which only has a single light receiving region 52 in the light receiving face 51. The light detector 50 illustrated in FIG. 18 has two wiring regions 54 isolated from one another via the light receiving region 52 in the X direction. Because there are two wiring regions 54, two wiring regions 14 of the substrate 11 are provided for electrical connection to the light detector 50 (see FIG. 6). Employing a light detector 50 having such a structure can reduce the number of wiring regions 14 of the substrate 11, which in turn can reduce the size of the light emitting device 401 in the Z direction.

### Head-Mounted Display

FIG. 19 is a lateral side view schematically showing an example of a head-mounted display 600 equipped with a light emitting devices 200, 300, 400, or 401 according to the embodiments of the present disclosure. A light emitting device 200 will be used as an example in the explanation below, but the head-mounted display 600 may include a light emitting device 300 instead of the light emitting device 200. This head-mounted display 600 includes a temple 650 and a waveguide 660 connected to the temple 650. The waveguide 660 has a light emission region, for example, a diffraction grating or the like. The laser light incident on the waveguide 660 can exit through the light emission region of the waveguide 660 towards the retina of an eye of the user.

One end of the temple 650 is positioned on the waveguide 660 side, i.e., user's nose side, and the other end of the temple 650 is on the opposite side, i.e., user's ear side. In FIG. 19, the direction from one end to the other end of the temple 650 is in parallel with the direction of the optical axis of the light exiting from the light emitting device 200. In the case of the example shown in the drawing, the X. Y, and Z directions of the light emitting device 200 in FIG. 1 coincide with the X, Y, and Z directions of the light emitting device 200 in FIG. 19. Based on a user wearing the head-mounted display 600, the optical axis direction is substantially in parallel with the direction from the ear to the nose of the user (or the reverse direction).

In the example of head-mounted display 600 shown in FIG. 19, the light emitting device 200 is supported in the temple 650. In FIG. 19, the lateral face of the light emitting device 200 is visibly drawn, but in reality, the exterior of the light emitting device 200 is not visually recognizable from the outside. The size of the light emitting device 200 shown in FIG. 1 in the X direction is, for example, 3 mm to 15 mm which is smaller than the size in the Z direction (the direction in which the temple 650 is elongated in FIG. 19).

The light emitting device 200 is preferably installed in the head-mounted display 600 such that the direction of the optical axis of the light exiting from the light emitting device 200 is in parallel with the direction in which the temple of the head-mounted display 600 is elongated. The light emitting device 200 reduced in size in the direction perpendicular to the optical axis can reduce the width of the temple 650 in the X direction. Furthermore, the width of the temple 650 in the Y direction can be reduced by employing a light emitting device 300 in which the size in the height direction can be reduced. As shown in the drawing, the temple 650 has a length that covers the distance from the eye to the ear of the user. Thus, an excessive reduction in size of the light emitting device 200 in the direction of the optical axis of the light exiting from the light emitting device 200 would not contribute to the size reduction of the head-mounted display 600.

In this embodiment, collimated beams of the first light, the second light, and the third light can be coaxially emitted from a narrow region of the light emitting device 200. The first light, the second light, and the third light are each a laser beam of one of red, green, and blue colors. The laser beam of each color is scanned by a MEMS element such as a micromirror before traveling through the waveguide 660 and eventually forms an image on the retina of the user. A color image may be displayed by using a field sequential method. In this case, the first light, the second light, and the third light are successively emitted. A light detector 50 included in the light emitting device 200 can be utilized to monitor the intensity of the first light, the second light, and the third light. The light detector may be provided on the outside of the light emitting device 200, or outside of the package 10 while being in the light emitting device 200. The light emitting device 200 (300) may be disposed in the head-mounted display 600 such that the X and Y directions in FIG. 1 respectively correspond to the Y and X directions in FIG. 19.

In the foregoing, certain embodiments of the present invention have been explained. The light emitting device according to the present invention, however, is not strictly limited to the light emitting device of the embodiments disclosed. In other words, the present invention is implementable without limiting the outer shape or the structure of a light emitting device to any of those disclosed by the embodiments. For example, a light emitting device according to the present invention may be one that has no protective device. Furthermore, it is not essential for the applicability of the present invention to include all of the constituent elements necessarily and fully. For example, in the event that a certain constituent element of a light emitting device disclosed by any of the embodiments is not disclosed in the claim scope, we claim the applicability of the invention disclosed in the claim scope by recognizing the design flexibility for a person of ordinary skill in the art for such a constituent element through the use of an alternative, an omission, a shape change, a change in the materials employed, or the like.

### INDUSTRIAL APPLICABILITY

The light emitting devices according to the embodiments can be used in head-mounted displays, projectors, lighting fixtures, displays, and the like.

### REFERENCE NUMERALS

10: package, 10A: light incident face, 10B: light extraction face, 11, 11A: substrate, 11M: mounting face, 11Ma: first mounting face, 11Mb: second mounting face, 11P: peripheral region, 12: lateral wall part, 13: light transmitting region, 14: wiring region, 15: upper part. 16: first cap, 18a: first mounting region, 18b: second mounting region, 19: opening, 20, 20a, 20b, 20c, 20d: light emitting element, 22a: first light, 22b: second light, 22c: third light, 22d: fourth light, 23a: first optical axis, 23b: second optical axis, 23c: third optical axis, 23d: fourth optical axis, 27a: first lateral face, 27b: second lateral face, 27c: third lateral face, 30: submount, 30M: upper face, 40: optical member, 50: light detector, 54: wiring region, 60A: protective device, 60B: temperature measuring element, 70: wire, 80: lens member, 81: lens flat face, 81a: first lens flat face, 81b: second lens flat face, 81c: third lens flat face, 82: lens face, 82a: first lens face, 82b: second lens face, 82c: third lens face. 83: lens shape, 83a: first lens shape, 83b: second lens shape, 83c: third lens shape. 85a: first lens optical axis, 85b: second lens optical axis, 85c: third lens optical axis, 90: beam combiner, 91: optical element, 120: second cap, 130: lid, 200, 300: light emitting device. 600: head-mounted display, 650: temple, 660: waveguide

1. A light emitting device comprising:
three or more light emitting elements, and
a package comprising,
a base having a mounting face on which the three or more light emitting elements are disposed and
a lateral wall part disposed around the three or more light emitting elements and having a light transmitting incident face; wherein
the three or more light emitting elements comprise,
a first light emitting element that emits first light having an emission peak at a first wavelength from a first emission point along a first optical axis,
a second light emitting element that emits second light having an emission peak at a second wavelength from a second emission point along a second optical axis, the second wavelength being different from the first wavelength, and
a third light emitting element that emits third light having an emission peak at a third wavelength from a third emission point along a third optical axis, the third wavelength being different from the first wavelength and the second wavelength, wherein
an angle formed by the first optical axis and the second optical axis in a top view when viewed in a first direction that is a direction normal to the mounting face is 3° to 45°,
a first interval between the first optical axis and the second optical axis increases as the first light and the second light respectively travel along the first optical axis and the second optical axis, and
the exiting first, second, and third lights respectively from the first, second, and third light emitting elements are incident on the incident face.

2. The light emitting device according to claim 1, wherein;
an angle formed by the second optical axis and the third optical axis in the top view is 3° to 45°, and
a second interval between the second optical axis and the third optical axis increases as the second light and the third light respectively travel along the second optical axis and the third optical axis.

3. The light emitting device according to claim 1, wherein the angle formed by the second optical axis and the third optical axis is 0° to 3°.

4. The light emitting device according to claim 1, further comprising one or more lens members, wherein:
the one or more lens members include a first lens shape and a second lens shape,
the first lens shape has a first lens face provided on a side facing the package or on a side located opposite the side facing the package,
the second lens shape has a second lens face provided on the same side as the first lens face,
the first light passes through the first lens face and the second light passes through the second lens face.

5. The light emitting device according to claim 4, wherein:
an optical axis of the first lens face is nonparallel with the first optical axis of the first light emitting element, and
an optical axis of the second lens face is nonparallel with the second optical axis of the second light emitting element.

6. The light emitting device according to claim 4, wherein:
the one or more lens members further include a third lens shape having a third lens face provided on the same side as the first lens face and the second lens face,
the third light passes through the third lens face, and
the optical axis of the third lens face is nonparallel with the third optical axis of the third light emitting element.

7. The light emitting device according to claim 6, wherein:
the first, second, and third lens shape are connected;
the first, second, and third lens shapes respectively have first, second, and third points on the face located opposite the first, second, and third lens faces, the points being respectively farthest from the first, second, and third lens faces in the second direction that is in parallel with the second optical axis,
the second lens shape is positioned between the first lens shape and the third lens shape, and
a distance from the second point to the second lens face is larger than a distance from the first point to the first lens face and a distance from the third point to the third lens face in the second direction, wherein
in a direction normal to a plane defined by the first direction and the second direction,
the first point is positioned closer to the second lens face than a midpoint of the first lens face is, and
the third point is positioned closer to the second lens face than a midpoint of the third lens face is.

8. The light emitting device according to claim 6, wherein:
the first, second, and third light respectively have first, second, and third beam shapes defined by their far field patterns; and
in the optical paths of the first, second, and third lights until they enter the one or more lens members, an interval between the boundary of the first beam shape and the second optical axis remains constant or increases as the first light travels along the first optical axis.

9. The light emitting device according to claim 6, further comprising a beam combiner for coaxially combining the first, second, and third lights that have respectively passed through the first, second, and third lens faces of the one or more lens members, and emitting composite light.

10. The light emitting device according to claim 1, further comprising a submount disposed on the mounting face of the base, the submount provided for mounting the three or more light emitting elements.

11. The light emitting device according to claim 10, further comprising a lens member having a first lens face, a second lens face, and a third lens face,
wherein, in the direction normal to the plane defined by the first direction and the second direction that is in parallel with the second optical axis, a distance between a point of intersection of the first lens face and the first optical axis and a point of intersection of the third lens face and the third optical axis is larger than the length of the submount.

12. The light emitting device according to claim 1 wherein the first, second, and third lights are respectively red light, green light, and blue light.

13. The light emitting device according to claim 1, wherein
the three or more light emitting elements further include a fourth light emitting element that emits fourth light having an emission peak at a fourth wavelength from a fourth emission point along a fourth optical axis, the fourth wavelength being different from the first, second, and third wavelengths,
the fourth light emitting element is disposed on the mounting face of the base,
the third optical axis and a fourth optical axis forms an angle of 3° to 45° in the top view, and
a third interval between the third optical axis and the fourth optical axis increases as the third light and the fourth light respectively travel along the third optical axis and a fourth optical axis.

14. The light emitting device according to claim 13, wherein the first, second, third, and fourth lights are respectively infrared light, red light, green light, and blue light.

15. The light emitting device according to claim 13, further comprising a submount disposed on the mounting face of the base, the submount provided for mounting the three or more light emitting elements.

16. The light emitting device according to claim 1, wherein the second light emitting element is located between the first light emitting element and the third light emitting element.

17. The light emitting device according to claim 10, wherein a wiring region electrically connected to at least one of the three or more light emitting elements is provided in a region located on one side of the submount in the mounting face.

18. The light emitting device according to claim 1, wherein
the first light emitting element has a first emission end face where the first emission point is located, and a first lateral face meeting the first emission end face and positioned on a second light emitting element side,
the second light emitting element has a second emission end face where the second emission point is located, and a second lateral face meeting the second emission end face and positioned on a first light emitting side, and
in the plan view when viewed in the direction normal to the second emission end face of the second light emitting element, a portion of the first lateral face of the first light emitting element overlaps the second emission end face of the second light emitting element in whole or part.

19. The light emitting device according to claim 18, wherein a length of the first lateral face in a direction perpendicular to the first emission end face of the first light emitting element is larger than a length of the second lateral face in a direction perpendicular to the second emission end face of the second light emitting element.

20. The light emitting device according to claim 1, wherein the three or more light emitting elements are semiconductor laser elements.
